(19) United States
(12) Patent Application Publication
(10) Pub. No.: US 2026/0255833 A1
(43) Pub. Date: Aug. 27, 2026

(54) DISPLAY PANEL AND DISPLAY APPARATUS

(71) Applicants: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(72) Inventors: Tiancheng YU, Beijing (CN); Yige QI, Beijing (CN); Ruqin ZHANG, Beijing (CN)

(73) Assignees: Chengdu BOE Optoelectronics Technology Co., Ltd., Chengdu, Sichuan (CN); BOE Technology Group Co., Ltd., Beijing (CN); Beijing BOE Technology Development Co., Ltd., Beijing (CN)

(21) Appl. No.: 18/993,045

(22) PCT Filed: Apr. 17, 2024
(86) PCT No.: PCT/CN2024/088414

§ 371 Date: Jan. 10, 2025

(30) Foreign Application Priority Data
May 31, 2023 (CN) 202310639906.7

(51) Int. Cl. H10K 59/35; H10K 59/38; H10K 101/20

(52) U.S. Cl. CPC H10K 59/353; H10K 59/38; H10K 2101/20

(57) ABSTRACT

A display panel includes a first electrode layer, a second electrode layer and a light-emitting layer. The first electrode layer includes a reflective electrode layer. The second electrode layer is arranged opposite the first electrode layer, and includes a transflective electrode layer. The light-emitting layer is located between the first electrode layer and the second electrode layer. The light-emitting layer includes a plurality of light-emitting portions, and a material of each light-emitting portion includes a main body material and a fluorescent material. The plurality of light-emitting portions include a plurality of red light-emitting portions, a plurality of blue light-emitting portions and a plurality of green light-emitting portions; a material of at least one red light-emitting portion further includes a green thermally-activated delayed fluorescent material; and a material of at least one green light-emitting portion further includes a blue thermally-activated delayed fluorescent material.

### CROSS-REFERENCE TO RELATED APPLICATIONS

This application is a national phase entry under 35 USC 371 of International Patent Application No. PCT/CN2024/088414 filed on Apr. 17, 2024, which claims priority to Chinese Patent Application No. 202310639906.7, filed on May 31, 2023, which are incorporated in embodiments of this present disclosure by reference in their entirety.

### TECHNICAL FIELD

The present disclosure relates to the field of display technologies, and in particular, to a display panel and a display apparatus.

### BACKGROUND

Organic light-emitting diodes (OLEDs) have been widely used in the display field due to advantages of self-light emitting, low driving voltage, high light-emitting efficiency, fast response speed, flexible display and the like.

### SUMMARY

In an aspect, a display panel is provided. The display panel includes a first electrode layer, a second electrode layer and a light-emitting layer. The first electrode layer includes a reflective electrode layer. The second electrode layer is arranged opposite to the first electrode layer, and the second electrode layer includes a transflective electrode layer. The light-emitting layer is located between the first electrode layer and the second electrode layer. The light-emitting layer includes a plurality of light-emitting portions, and a material of each of the plurality of light-emitting portions includes a main body material and a fluorescent material. The plurality of light-emitting portions include a plurality of red light-emitting portions, a plurality of blue light-emitting portions and a plurality of green light-emitting portions. A material of at least one red light-emitting portion of the plurality of red light-emitting portions further includes a green thermally-activated delayed fluorescent material, and a material of at least one green light-emitting portion of the plurality of green light-emitting portions further includes a blue thermally-activated delayed fluorescent material.

In some embodiments, a concentration of the blue thermally-activated delayed fluorescent material of the at least one green light-emitting portion is greater than a concentration of the fluorescent material of the at least one green light-emitting portion.

In some embodiments, a concentration of the blue thermally-activated delayed fluorescent material of the at least one green light-emitting portion is in a range of 35% to 45%, and a concentration of the fluorescent material of the at least one green light-emitting portion is less than 1%.

In some embodiments, a highest occupied molecular orbital energy level of the green thermally-activated delayed fluorescent material is −5.2 eV, and a lowest unoccupied molecular orbital energy level of the green thermally-activated delayed fluorescent material is −3.1 eV; and/or, a highest occupied molecular orbital energy level of the blue thermally-activated delayed fluorescent material is −5.8 eV, and a lowest unoccupied molecular orbital energy level of the blue thermally-activated delayed fluorescent material is −3.0 eV.

In some embodiments, a peak of a photoluminescence spectrum of the green thermally-activated delayed fluorescent material is in a range of 500 nm to 550 nm; and/or a peak of a photoluminescence spectrum of the blue thermally-activated delayed fluorescent material is in a range of 450 nm to 500 nm.

In some embodiments, the green thermally-activated delayed fluorescent material and the blue thermally-activated delayed fluorescent material each include an electron donor functional group and an electron acceptor functional group. An electron donating ability of the electron donor functional group of the green thermally-activated delayed fluorescent material is greater than an electron donating ability of the electron donor functional group of the blue thermally-activated delayed fluorescent material.

In some embodiments, the electron donor functional group of the green thermally-activated delayed fluorescent material and/or the electron donor functional group of the blue thermally-activated delayed fluorescent material include a carbazole structure, a thiophene structure or a triphenylamine structure. The electron acceptor functional group of the green thermally-activated delayed fluorescent material and/or the electron acceptor functional group of the blue thermally-activated delayed fluorescent material include a cyano structure, an anthraquinone structure or a diphenyl sulfone structure.

In some embodiments, in a case where a first direction is parallel to a line of sight, a peak of a photoluminescence spectrum of the at least one red light-emitting portion is in a range of 621 nm to 631 nm, a peak of a photoluminescence spectrum of the at least one green light-emitting portion is in a range of 525 nm to 535 nm, and a peak of a photoluminescence spectrum of a blue light-emitting portion is in a range of 455 nm to 465 nm. The first direction is perpendicular to a plane where the first electrode layer of the display panel is located. In a case where an angle between the first direction and the line of sight is 30°, the peak of the photoluminescence spectrum of the at least one red light-emitting portion is in a range of 618 nm to 628 nm, the peak of the photoluminescence spectrum of the at least one green light-emitting portion is in a range of 520 nm to 530 nm, and the peak of the photoluminescence spectrum of the blue light-emitting portion is in a range of 453 nm to 463 nm. In a case where the angle between the first direction and the line of sight is 45°, the peak of the photoluminescence spectrum of the at least one red light-emitting portion is in a range of 619 nm to 629 nm, the peak of the photoluminescence spectrum of the at least one green light-emitting portion is in a range of 523 nm to 533 nm, and the peak of the photoluminescence spectrum of the blue light-emitting portion is in a range of 451 nm to 461 nm. In a case where the angle between the first direction and the line of sight is 60°, the peak of the photoluminescence spectrum of the at least one red light-emitting portion is in a range of 619 nm to 629 nm, the peak of the photoluminescence spectrum of the at least one green light-emitting portion is in a range of 523 nm to 533 nm, and the peak of the photoluminescence spectrum of the blue light-emitting portion is in a range of 452 nm to 462 nm.

In some embodiments, at least two light-emitting portions are disposed in a first direction between the first electrode layer and the second electrode layer that are arranged opposite to each other. The first direction is perpendicular to a plane where the first electrode layer is located. The display panel further includes a charge generation layer, and the charge generation layer is located between two adjacent light-emitting portions that are disposed in the first direction. The charge generation layer is configured to provide carriers to the two adjacent light-emitting portions.

In some embodiments, the at least two light-emitting portions include a first green light-emitting portion and a second green light-emitting portion. A material of the first green light-emitting portion and/or a material of the second green light-emitting portion include the blue thermally-activated delayed fluorescent material.

In some embodiments, the at least two light-emitting portions include a first red light-emitting portion and a second red light-emitting portion. A material of the first red light-emitting portion and/or a material of the second red light-emitting portion include the green thermally-activated delayed fluorescent material.

In some embodiments, the display panel further includes a red filter portion and a green filter portion. The red filter portion is located on a side of the second electrode layer away from the first electrode layer, and an orthographic projection of the red filter portion on a reference plane covers an orthographic projection of a corresponding red light-emitting portion on the reference plane. The green filter portion is located on the side of the second electrode layer away from the first electrode layer, and an orthographic projection of the green filter portion on the reference plane covers an orthographic projection of a corresponding green light-emitting portion on the reference plane. The reference plane is parallel to a surface of the first electrode layer close to the second electrode layer.

In some embodiments, the display panel further includes a blue filter portion. The blue filter portion is located on the side of the second electrode layer away from the first electrode layer, and an orthographic projection of the blue filter portion on the reference plane covers an orthographic projection of a corresponding blue light-emitting portion on the reference plane.

In some embodiments, the display panel further includes a red filter portion. The red filter portion is located on a side of the second electrode layer away from the first electrode layer, and an orthographic projection of the red filter portion on a reference plane covers an orthographic projection of a corresponding red light-emitting portion on the reference plane. A material of at least one blue light-emitting portion of the plurality of blue light-emitting portions further includes a red thermally-activated delayed fluorescent material. The reference plane is parallel to a surface of the first electrode layer close to the second electrode layer.

In some embodiments, the display panel further includes a first protective adhesive layer. The first protective adhesive layer is located on a side of the second electrode layer away from the first electrode layer, and a surface of the first protective adhesive layer away from the first electrode layer is substantially parallel to the reference surface.

In another aspect, a display panel is provided. The display panel includes a first electrode layer, a second electrode layer, a light-emitting layer and a red filter portion. The first electrode layer includes a reflective electrode layer. The second electrode layer is arranged opposite to the first electrode layer, and the second electrode layer includes a transflective electrode layer. The light-emitting layer is located between the first electrode layer and the second electrode layer. The light-emitting layer includes a plurality of light-emitting portions, and a material of each of the plurality of light-emitting portions includes a main body material and a fluorescent material. The plurality of light-emitting portions include a plurality of red light-emitting portions, a plurality of blue light-emitting portions and a plurality of green light-emitting portions. A material of at least one red light-emitting portion of the plurality of red light-emitting portions further includes a green thermally-activated delayed fluorescent material. The red filter portion is located on a side of the second electrode layer away from the first electrode layer, and an orthographic projection of the red filter portion on a reference plane covers an orthographic projection of a corresponding red light-emitting portion on the reference plane. The reference plane is parallel to a surface of the first electrode layer close to the second electrode layer.

In some embodiments, the red filter portion is configured to transmit red light with a wavelength greater than or equal to 600 nm.

In some embodiments, the display panel further includes a second protective adhesive layer. The second protective adhesive layer is partially located on a side of the red filter portion away from the second electrode layer, and partially located on the side of the second electrode layer away from the first electrode layer. A surface of the second protective adhesive layer away from the first electrode layer is substantially parallel to the reference plane.

In some embodiments, at least two light-emitting portions are disposed in a first direction between the first electrode layer and the second electrode layer that are arranged opposite to each other. The first direction is perpendicular to a plane where the first electrode layer is located. The display panel further includes a charge generation layer. The charge generation layer is located between two adjacent light-emitting portions that are disposed in the first direction, and the charge generation layer is configured to provide carriers to the two adjacent light-emitting portions.

In some embodiments, the at least two light-emitting portions include a first red light-emitting portion and a second red light-emitting portion. A material of the first red light-emitting portion and/or a material of the second red light-emitting portion include the green thermally-activated delayed fluorescent material.

In yet another aspect, a display apparatus is provided. The display apparatus includes the display panel as described in any one of the above embodiments.

### BRIEF DESCRIPTION OF THE DRAWINGS

In order to describe technical solutions in the present disclosure more clearly, accompanying drawings to be used in some embodiments of the present disclosure will be introduced briefly. Obviously, the accompanying drawings to be described below are merely accompanying drawings in some embodiments of the present disclosure, and a person of ordinary skill in the art can obtain other drawings according to these drawings. In addition, the accompanying drawings to be described below may be regarded as schematic diagrams, but are not limitations on actual sizes of products, actual processes of methods and actual timings of signals involved in the embodiments of the present disclosure.

FIG. 1 is a structural diagram of a display apparatus, in accordance with some embodiments;

FIG. 2 is a structural diagram of film layers of a display panel, in accordance with some embodiments;

FIG. 3 is a structural diagram showing one light-emitting portion being disposed in a first direction between a first electrode layer and a second electrode layer, in accordance with some embodiments;

FIG. 4 is a diagram of energy transfer of a main body material and a fluorescent material, in accordance with some embodiments;

FIG. 5 is a diagram of energy transfer of a green TADF material, in accordance with some embodiments;

FIG. 6 is a spectrogram of a red light-emitting portion, in accordance with some embodiments;

FIG. 7 is a diagram of energy transfer of a blue TADF material, in accordance with some embodiments;

FIG. 8 is a spectrogram of a green light-emitting portion, in accordance with some embodiments;

FIG. 9 is a spectrogram of a blue light-emitting portion, in accordance with some embodiments;

FIG. 10 is a diagram of test results of chromaticity coordinates, in accordance with some embodiments;

FIG. 11 is a diagram of test results of color shifts, in accordance with some embodiments;

FIG. 12 is a diagram of test results of luminance decay curves, in accordance with some embodiments;

FIG. 13 is a structural diagram showing two light-emitting portions being disposed in a first direction between a first electrode layer and a second electrode layer, in accordance with some embodiments;

FIG. 14 is a structural diagram of a display panel including a red filter portion and a green filter portion, in accordance with some embodiments;

FIG. 15 is a transmission spectrogram of a red filter portion, in accordance with some embodiments;

FIG. 16 is a structural diagram of a display panel including a red filter portion, a green filter portion and a blue filter portion, in accordance with some embodiments;

FIG. 17 is a structural diagram of a display panel including a red filter portion, in accordance with some embodiments;

FIG. 18 is another diagram of test results of chromaticity coordinates, in accordance with some embodiments;

FIG. 19 is another diagram of test results of color shifts, in accordance with some embodiments;

FIG. 20 is another diagram of test results of luminance decay curves, in accordance with some embodiments;

FIG. 21 is another transmission spectrogram of a red filter portion, in accordance with some embodiments;

FIG. 22 is yet another diagram of test results of color coordinates, in accordance with some embodiments;

FIG. 23 is yet another diagram of test results of color shifts, in accordance with some embodiments; and

FIG. 24 is yet another diagram of test results of luminance decay curves, in accordance with some embodiments.

### DETAILED DESCRIPTION

The technical solutions in some embodiments of the present disclosure will be described clearly and completely with reference to the accompanying drawings. Obviously, the described embodiments are merely some but not all embodiments of the present disclosure. All other embodiments obtained by a person of ordinary skill in the art based on embodiments of the present disclosure shall be included in the protection scope of the present disclosure.

Unless the context requires otherwise, throughout the specification and the claims, the term “comprise” and other forms thereof such as the third-person singular form “comprises” and the present participle form “comprising” are construed as an open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms “first” and “second” are only used for descriptive purposes, and cannot be construed as indicating or implying the relative importance or implicitly indicating the number of indicated technical features. Thus, features defined by “first” or “second” may explicitly or implicitly include one or more of the features. In the description of the embodiments of the present disclosure, the term “a plurality of” or “the plurality of” means two or more unless otherwise specified.

In the description of some embodiments, terms such as “coupled” and derivatives thereof may be used. The term “connected” should be understood in a broad sense. For example, the term “connected” may represent a fixed connection, a detachable connection, or a one-piece connection, or may represent a direct connection, or may represent an indirect connection through an intermediate medium.

The phrase “at least one of A, B and C” has the same meaning as the phrase “at least one of A, B, or C”, and they both include the following combinations of A, B, and C: only A, only B, only C, a combination of A and B, a combination of A and C, a combination of B and C, and a combination of A, B, and C.

The phrase “A and/or B” includes following three combinations: only A, only B, and a combination of A and B.

The use of “applicable to” or “configured to” herein indicates an open and inclusive expression, which does not exclude devices that are applicable to or configured to perform additional tasks or steps.

In addition, the use of the phrase “based on” is meant to be open and inclusive, since a process, step, calculation or other actions that is “based on” one or more of the stated conditions or values may, in practice, be based on additional conditions or values other than those stated.

The term such as “substantially” as used herein includes a stated value and an average value within an acceptable range of deviation of a particular value that is determined by a person of ordinary skill in the art in considering measurement in question and errors associated with a particular quantity of measurement (i.e., limitations of a measurement system).

The terms “parallel” and “perpendicular” as used herein include a stated condition and conditions similar to the stated condition, and the range of the similar conditions is within the acceptable range of deviation that is determined by a person of ordinary skill in the art in consideration of the measurement in question and the error associated with the measurement of a specific quantity (i.e., the limitation of the measurement system). For example, the term “parallel” includes absolute parallelism and approximate parallelism, and an acceptable range of deviation of the approximate parallelism may be, for example, a deviation within 5°. The term “perpendicular” includes absolute perpendicularity and approximate perpendicularity, and an acceptable range of deviation of the approximate perpendicularity may also be, for example, a deviation within 5°.

It will be understood that, in a case where a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views as idealized exemplary drawings. In the drawings, thicknesses of layers and sizes of regions are enlarged for clarity. Thus, variations in shape with respect to the accompanying drawings due to, for example, manufacturing technologies and/or tolerances may be envisaged. Therefore, the exemplary embodiments should not be construed as being limited to the shapes of the regions shown herein, but including shape deviations due to, for example, manufacturing. For example, an etched region shown to have a rectangular shape generally has a curved feature. Therefore, the regions shown in the accompanying drawings are schematic in nature, and their shapes are not intended to show actual shapes of the regions in a device, and are not intended to limit the scope of the exemplary embodiments.

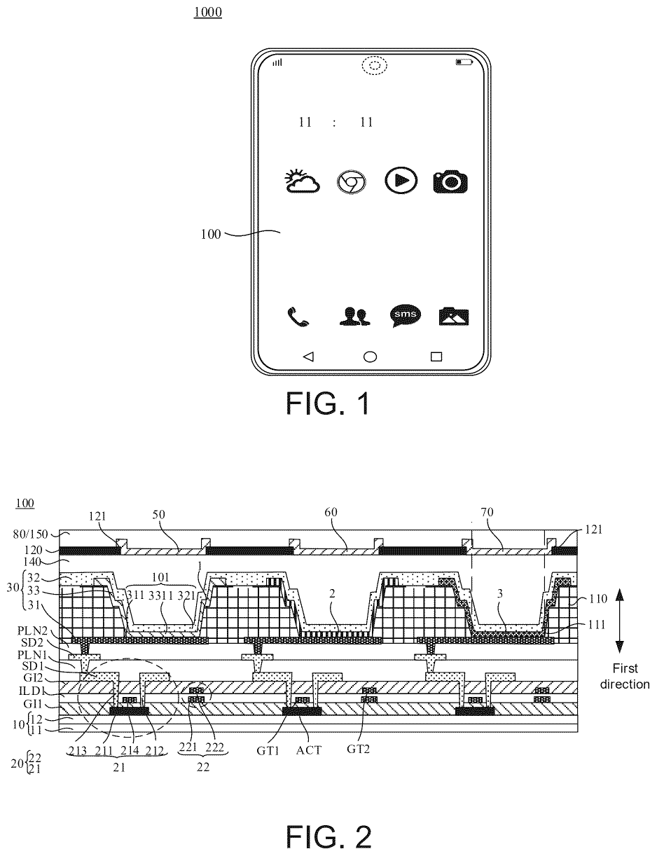

Some embodiments of the present disclosure provide a display apparatus 1000. As shown in FIG. 1, the display apparatus 1000 may be any apparatus that displays images whether in motion (e.g., videos) or stationary (e.g., still images) and whether textual or graphical. For example, the display apparatus 1000 may be any product or component having a display function, such as a television, a laptop computer, a tablet computer, a mobile phone, a personal digital assistant (PDA), a navigator, a wearable device, an augmented reality (AR) device, a virtual reality (VR) device.

The display apparatus 1000 may be an organic electroluminescent diode display apparatus, a quantum dot light-emitting diode (QLED) display apparatus or an active-matrix organic light-emitting diode (AMOLED) display apparatus. The embodiments of the present disclosure are described by taking an example in which the display apparatus is an OLED display apparatus.

In some embodiments, the display apparatus 1000 includes a display panel 100.

As shown in FIG. 2, the display panel 100 includes a substrate 10, a driving circuit stack 20, and a light-emitting stack 30.

The substrate 10 may be a flexible substrate 10 or a rigid substrate 10. A material of the rigid substrate 10 may be glass, and a material of the flexible substrate 10 may be polyimide (PI).

It should be noted that the substrate 10 may have a single-layer structure or a multi-layer structure. For example, in a case where the substrate 10 has a multi-layer structure, the substrate 10 may include a base 11 and a buffer layer 12 disposed on the base 11. A material of the buffer layer 12 may include silicon oxide or silicon nitride. The embodiments of the present disclosure do not specifically limit the material and structure of the substrate 10.

As shown in FIG. 2, the driving circuit stack 20 is disposed on a side of the substrate 10. The driving circuit stack 20 includes a plurality of thin film transistors 21 and storage capacitor(s) 22.

The thin film transistor 21 is, for example, an oxide thin film transistor. The oxide thin film transistor has a high carrier mobility, which can improve a response speed of the thin film transistor 21. For example, a structure of the driving circuit stack 20 may be 2T1C, 5T2C, 6T1C, 6T2C, 7T1C, 7T2C or 9T2C, which are not listed one by one in the embodiments of the present disclosure. For example, the structure of the driving circuit stack 20 is 7T1C. The structure of the driving circuit stack 20 is aTbC, which means that the driving circuit includes a thin film transistors 21 and b storage capacitors 22.

The thin film transistor 21 includes an active layer 211, a source 212, a drain 213 and a gate 214. The source 212 and the drain 213 are in contact with the active layer 211. It will be noted that the source 212 and the drain 213 may be interchanged. The storage capacitor 22 includes a first electrode plate 221 and a second electrode plate 222 which are arranged opposite to each other.

The light-emitting stack 30 is located on a side of the driving circuit stack 20 away from the substrate 10. The light-emitting stack 30 includes a first electrode layer 31, a light-emitting functional layer 33 and a second electrode layer 32 which are stacked in sequence.

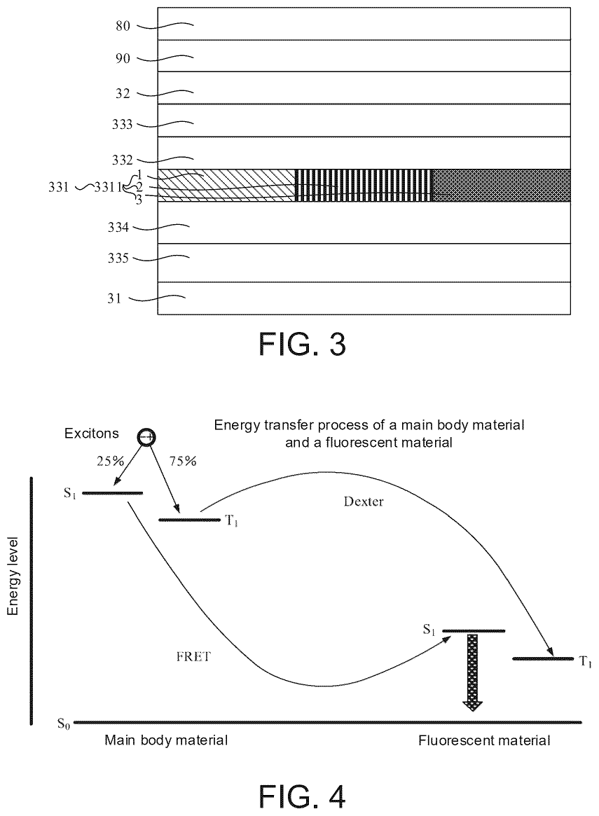

As shown in FIG. 3, the light-emitting functional layer 33 may include only a light-emitting layer 331. Alternatively, in addition to the light-emitting layer, the light-emitting functional layer 33 includes at least one of an electron transporting layer (ETL) 332, an electron injection layer (EIL) 333, a hole transporting layer (HTL) 334 and a hole injection layer (HIL) 335.

As shown in FIG. 2, the first electrode layer 31 includes a plurality of first electrodes 311, and the second electrode layer 32 includes a plurality of second electrodes 321. A first electrode 311 is arranged opposite to a second electrode 321. That is, the first electrode layer 31 is arranged opposite to the second electrode layer 32. The light-emitting layer 331 includes a plurality of light-emitting portions 3311. The first electrode 311 and the second electrode 321 that are arranged opposite to each other, and the light-emitting portion 3311 located between the first electrode 311 and the second electrode 321 form a light-emitting device 101.

For example, the first electrode 311 may be electrically connected to a source 212 or a drain 213 of a thin film transistor 21 of the plurality of thin film transistors 21 that is serves as a driving transistor. FIG. 2 shows an example where the first electrode 311 is electrically connected to the drain 213 of the thin film transistor 21. It should be noted that the first electrode 311 is an anode of the light-emitting device 101, and the second electrode 321 is a cathode of the light-emitting device 101. Alternatively, the first electrode 311 is the cathode of the light-emitting device 101, and the second electrode 321 is the anode of the light-emitting device 101. The embodiments of the present disclosure are described by taking an example where the first electrode 311 is the anode of the light-emitting device 101, and the second electrode 321 is the cathode of the light-emitting device 101. For example, as shown in FIG. 2, the second electrode 321 (cathode) has a whole-layer structure. That is, voltage values on second electrodes 321 of different light-emitting devices 101 are equal.

The first electrode layer 31 includes a reflective electrode layer. That is, the first electrode 311 includes a reflective electrode, and the reflective electrode is used to reflect light incident on the first electrode 311. The first electrode 311 can have a single-layer structure or a stacked structure. For example, in a case where the first electrode 311 has a stacked structure, the first electrode 311 includes indium tin oxide (ITO), silver (Ag) and ITO that are stacked. The reflective electrode refers to an electrode with reflectivity greater than 90%.

The second electrode layer 32 includes a transflective electrode layer. That is, the second electrode 321 includes a transflective electrode. The transflective electrode is used to reflect part of light incident on the second electrode 321, and transmit part of the light incident on the second electrode 321. The transflective electrode refers to an electrode with reflectivity in a range of 50% to 60%. In this way, the first electrode 311 and the second electrode 321 form a resonant cavity. The light-emitting portion 3311 is located between the first electrode 311 and the second electrode 321. That is, the light-emitting portion 3311 is located within the resonant cavity. Intensity of light of a certain wavelength emitted by the light-emitting portion 3311 is increased, and a spectrum of the light of the certain wavelength emitted by the light-emitting portion 3311 is narrowed. The resonant cavity may make most of the light emitted by the light-emitting portion 3311 exit from the display panel 100, thereby improving light-emitting efficiency of the light-emitting device 101.

A light-emitting principle of the light-emitting device 101 is described below with examples. As shown in FIG. 4, the light-emitting portion 3311 includes a main body material and a fluorescent material. The first electrode 311 provides holes to the light-emitting portion, and the second electrode 321 provides electrons to the light-emitting portion 3311. Combination of a hole and an electron can cause an organic molecule in the main body material to transition from a ground state S₀ to an excited state to form an exciton (the main body material does not emit light, and its function is to transfer energy to the fluorescent material and excite an organic molecule in the fluorescent material to transition from a ground state to an excited state). Excitons are divided into two categories, one is singlet excitons S₁, the other is triplet excitons T₁. According to statistical rules of electron spin, a ratio of singlet excitons S₁ to triplet excitons T₁ is 1:3. According to principles of quantum mechanics, an electron-hole pair in the singlet exciton S₁ has opposite spin directions and can transition to the ground state S₀, and an electron-hole pair in the triplet exciton T₁ has the same spin direction and cannot transition to the ground state S₀. An energy difference between the triplet state T₁ and the singlet state S₁ in the main body material is large, and it is difficult for the triplet exciton T₁ to transition to a singlet exciton S₁ through reverse intersystem crossing (RISC). The singlet exciton S₁ in the main body material enables the organic molecule in the fluorescent material to receive energy and transition from the ground state S₀ to the excited state through Foster resonance energy transfer (FRET). In this way, the organic molecule in the fluorescent material forms a singlet exciton S₁. The triplet exciton T₁ in the main body material enables an organic molecule in the fluorescent material to receive energy and transition from the ground state S₀ to the excited state through electron exchange excitation transfer (Dexter excitation transfer, Dexter for short). In this way, the organic molecule in the fluorescent material forms a triplet exciton T₁. Singlet excitons S₁ in the fluorescent material are unstable and easily return from the excited state to the ground state S₀. The singlet excitons S₁ in the fluorescent material return from the excited state to the ground state S₀, and the fluorescent material emits light at the same time.

In some embodiments, as shown in FIG. 3, the plurality of light-emitting portions 3311 include a plurality of red light-emitting portions 1, a plurality of green light-emitting portions 2, and a plurality of blue light-emitting portions 3. The red light-emitting portion 1 includes a main body material and a red fluorescent material, so that the red light-emitting portion 1 can emit red light. The green light-emitting portion 2 includes a main body material and a green fluorescent material, so that the green light-emitting portion 2 can emit green light. The blue light-emitting portion 3 includes a main body material and a blue fluorescent material, so that the blue light-emitting portion 3 can emit blue light. The plurality of red light-emitting portions 1, the plurality of blue light-emitting portions 3, and the plurality of green light-emitting portions 2 cooperate with each other to achieve full-color display of the display panel. For example, the plurality of red light-emitting portions 1, the plurality of blue light-emitting portions 3, and the plurality of green light-emitting portions 2 cooperate with each other to enable the display panel 100 to display a white screen.

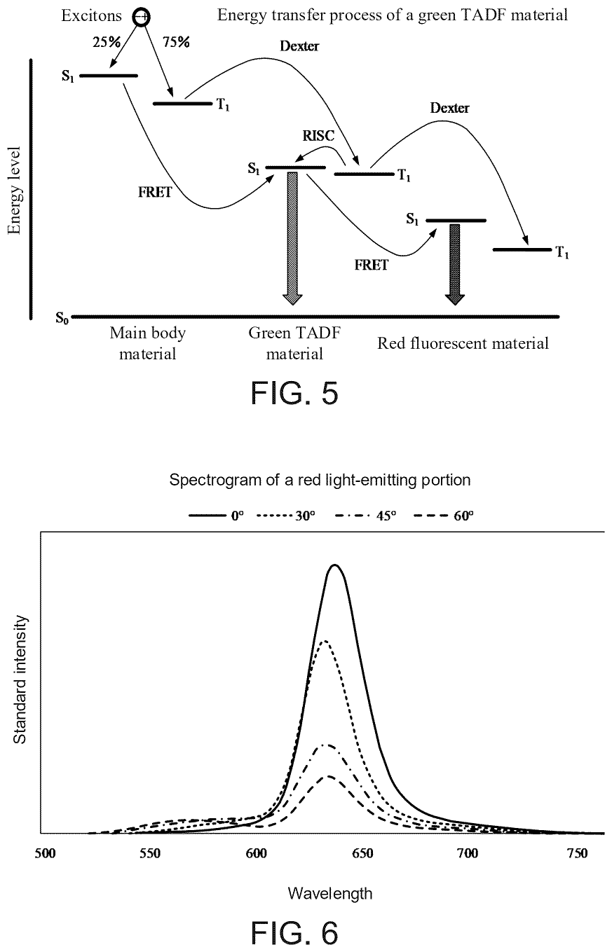

In some embodiments, as shown in FIG. 5, a material of at least one red light-emitting portion 1 further includes a green thermally-activated delayed fluorescence material (TADF). In this way, singlet excitons S₁ in the main body material in the red light-emitting portion 1 transfer energy to organic molecules in the green TADF material, and the organic molecules transition from the ground state S₀ to the excited state to form singlet excitons S₁. Triplet excitons T₁ in the main body material of the red light-emitting portion transfer energy to organic molecules in the green TADF material, and the organic molecules transition from the ground state S₀ to the excited state to form triplet excitons T₁. Some singlet excitons in the green TADF material transfer energy to organic molecules in the fluorescent material, the organic molecules transition from the ground state S₀ to the excited state to form singlet excitons S₁, the singlet excitons S₁ transition to the ground state S₀, and the red fluorescent material emits red light. Some singlet excitons S₁ in the green TADF material transition to the ground state S₀, and the green TADF material emits green light (e.g., light with a peak wavelength in a range of 500 nm to 550 nm in spectrum). That is, there is incomplete energy transfer among the main body material, the green thermally-activated delayed fluorescent material and the fluorescent material. Complete energy transfer means that the energy in the main body material is completely transferred to the fluorescent material. This way, only the fluorescent material emits light.

The energy difference between the triplet state T₁ and the singlet state S₁ in the green TADF material is small, and the triplet exciton T₁ can easily transition to the singlet state S₁ through RISC. In this way, triplet excitons T₁ in the green TADF material are transitioned to singlet excitons S₁ through RISC, which can increase the number of singlet excitons S₁ in the green TADF material and can in turn increase the number of singlet excitons S₁ in the fluorescent material, thereby improving light-emitting efficiency of the fluorescent material.

In some embodiments, as shown in FIG. 5, an energy level of the green thermally-activated delayed fluorescence material is located between energy levels of the main body material and the red fluorescent material of the at least one red light-emitting portion. Compared with a case where the main body material directly transfers energy to the fluorescent material, the green TADF material of the embodiment of the present disclosure can reduce a barrier height that needs to be overcome for a single energy transfer, which may in turn improve light-emitting efficiency of the red fluorescent material. A highest occupied molecular orbital (HOMO) energy level and a lowest unoccupied molecular orbital (LUMO) energy level of the green TADF material can be set according to actual conditions. For example, the highest occupied molecular orbital energy level of the green TADF material is −5.2 eV, and the lowest unoccupied molecular orbital energy level of the green TADF material is −3.1 eV. A difference between the lowest unoccupied molecular orbital energy level and the highest occupied molecular orbital energy level is 2.1 eV.

The green thermally-activated delayed fluorescent material includes an electron donor functional group and an electron acceptor functional group. For example, the electron donor functional group has a carbazole structure, a thiophene structure or a triphenylamine structure, which are not listed one by one in the embodiments of the present disclosure. The electron acceptor functional group has a cyano structure, anthraquinone structure or a diphenyl sulfone structure, which are not listed one by one in the embodiments of the present disclosure.

In the related art, an observer's line of sight forms an angle with a first direction (the first direction is perpendicular to a plane where the first electrode layer of the display panel is located). As shown in FIG. 6, as the angle increases, an intensity of a red light spectrum decreases and an intensity of a yellow light spectrum (e.g., light with a peak wavelength in a range of 550 nm to 600 nm in spectrum) increases in the red light-emitting portion 1. A ratio of the intensity of the red light to the intensity of the yellow light decreases. In a case where the display panel 100 displays a white screen and the angle is relatively large (for example, the angle is greater than 30°), the white screen turns yellow. The yellow light is a mixture of red light and green light.

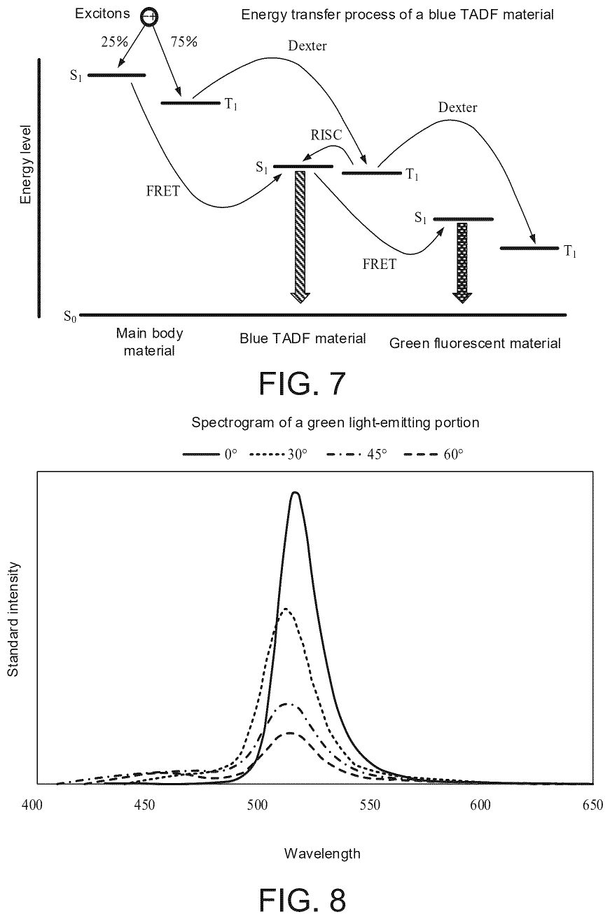

In order to solve the above problems, as shown in FIG. 7, a material of at least one green light-emitting portion 2 in the embodiments of the present disclosure further includes a blue thermally-activated delayed fluorescent material. Similar to the red light-emitting portion 1, there is also incomplete energy transfer among the main body material, the blue thermally-activated delayed fluorescent material and the fluorescent material of the green light-emitting portion 2. As shown in FIG. 8, as the angle increases, an intensity of a green light spectrum decreases and an intensity of blue light (e.g., light with a wavelength in a range of 450 nm to 500 nm) spectrum increases in the green light-emitting portion 2. The blue light in the green light-emitting portion 2 and the yellow light in the red light-emitting portion 1 can be mixed into white light, which can reduce a risk that the white screen of the display panel 100 turns yellow.

In some embodiments, a concentration of the blue thermally-activated delayed fluorescent material of the at least one green light-emitting portion 2 is greater than a concentration of the fluorescent material of the at least one green light-emitting portion 2. In this way, the incomplete energy transfer among the main body material, the blue thermally-activated delayed fluorescent material and the fluorescent material in the green light-emitting portion 2 can be obvious, and the intensity of the blue light spectrum of the green light-emitting portion 2 can be large, thereby reducing the risk that the white screen of the display panel 100 turns yellow.

For example, the concentration of the blue thermally-activated delayed fluorescent material is in a range of 35% to 45%. For example, the concentration is 35%, 40% or 45%, which are not listed one by one in the embodiments of the present disclosure. The concentration of the fluorescent material of the at least one green light-emitting portion 2 is less than 1%. For example, the concentration is 0.5% or 0.2%, which are not listed one by one in the embodiments of the present disclosure.

The blue thermally-activated delayed fluorescent material also includes an electron donor functional group and an electron acceptor functional group, and an electron donating ability of the electron donor functional group of the green thermally-activated delayed fluorescent material is greater than an electron donating ability of the electron donor functional group of the blue thermally-activated delayed fluorescent material.

In some embodiments, as shown in FIG. 7, an energy level of the blue thermally-activated delayed fluorescence material is located between energy levels of the main body material and the green fluorescent material of the at least one green light-emitting portion. Compared with a case where the main body material directly transfers energy to the fluorescent material, the blue TADF material of the embodiments of the present disclosure can reduce a barrier height that needs to be overcome for a single energy transfer, thereby improving light-emitting efficiency of the green fluorescent material. A highest occupied molecular orbital energy level and a lowest unoccupied molecular orbital energy level of the blue TADF material can be set according to actual conditions. For example, the highest occupied molecular orbital energy level of the blue TADF material is −5.8 eV, and the lowest unoccupied molecular orbital energy level of the blue TADF material is −3.0 eV. A difference between the lowest unoccupied molecular orbital energy level and the highest occupied molecular orbital energy level is 2.8 eV.

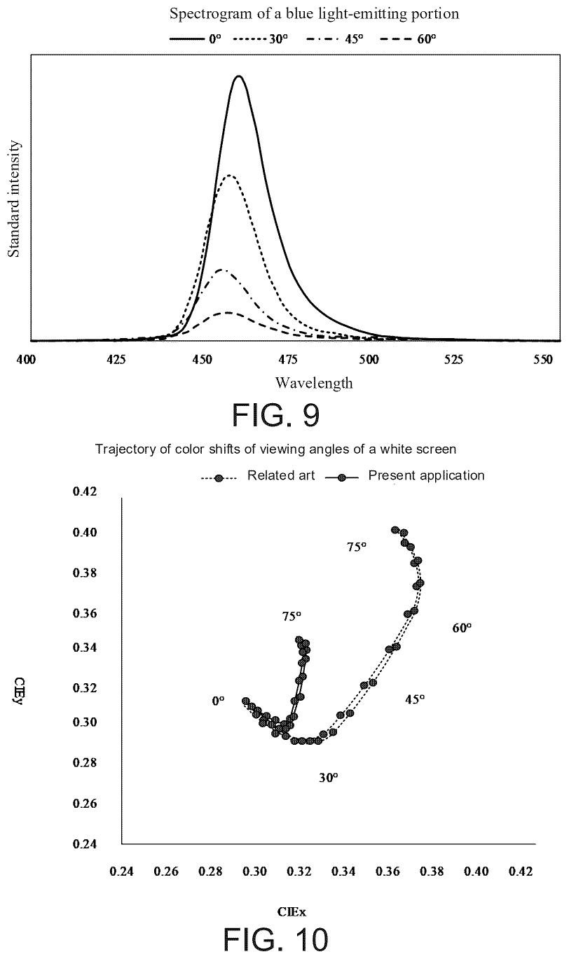

In some embodiments, as shown in FIGS. 6, 8 and 9, in a case where the first direction is parallel to the line of sight, a peak of a photoluminescence spectrum of the red light-emitting portion 1 is in a range of 621 nm to 631 nm, a peak of a photoluminescence spectrum of the green light-emitting portion 2 is in a range of 525 nm to 535 nm, and a peak of a photoluminescence spectrum of the blue light-emitting portion 3 is in a range of 455 nm to 465 nm. The first direction is perpendicular to a plane where the first electrode layer of the display panel is located.

In a case where the angle between the first direction and the line of sight is 30°, the peak of the photoluminescence spectrum of the red light-emitting portion 1 is in a range of 618 nm to 628 nm, the peak of the photoluminescence spectrum of the green light-emitting portion 2 is in a range of 520 nm to 530 nm, and the peak of the photoluminescence spectrum of the blue light-emitting portion 3 is in a range of 453 nm to 463 nm.

In a case where the angle between the first direction and the line of sight is 45°, the peak of the photoluminescence spectrum of the red light-emitting portion 1 is in a range of 619 nm to 629 nm, the peak of the photoluminescence spectrum of the green light-emitting portion 2 is in a range of 523 nm to 533 nm, and the peak of the photoluminescence spectrum of the blue light-emitting portion 3 is in a range of 451 nm to 461 nm.

In a case where the angle between the first direction and the line of sight is 60°, the peak of the photoluminescence spectrum of the red light-emitting portion 1 is in a range of 619 nm to 629 nm, the peak of the photoluminescence spectrum of the green light-emitting portion 2 is in a range of 523 nm to 533 nm, and the peak of the photoluminescence spectrum of the blue light-emitting portion 3 is in a range of 452 nm to 462 nm.

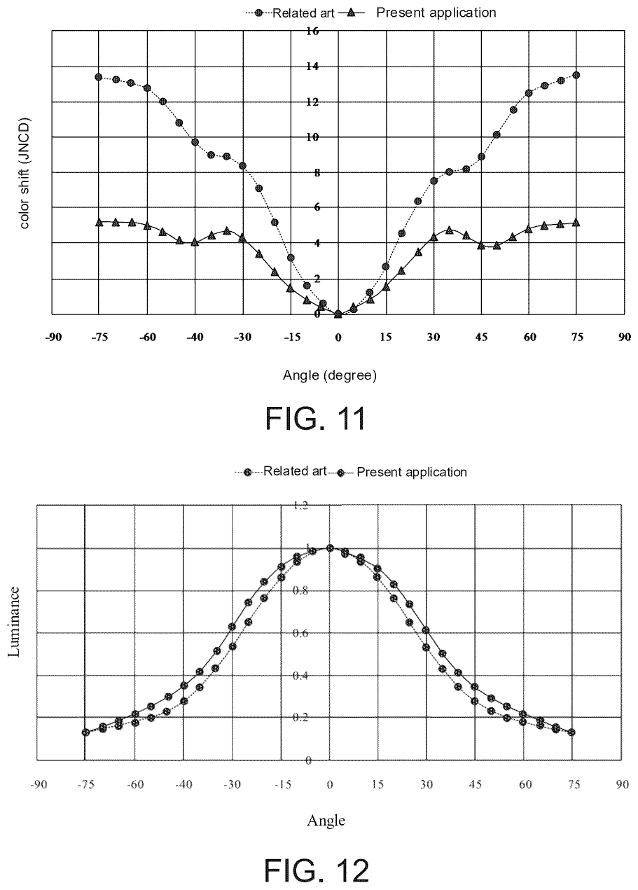

The display panel 100 is tested based on the above structure, and the following test results are obtained. As shown in FIG. 10, in a case where the angle is 75°, color coordinates of the display panel 100 in the present application are closer to white color coordinates compared with the related art. As shown in FIG. 11, in a case of the same angle, compared with the related art, a color shift value of the display panel 100 in the present application is reduced, and the display effect of the display panel 100 is better. As shown in FIG. 12, in a case of the same angle, compared with the related art, a luminance value of the display panel 100 in the present application is increased, and the display effect of the display panel 100 is better.

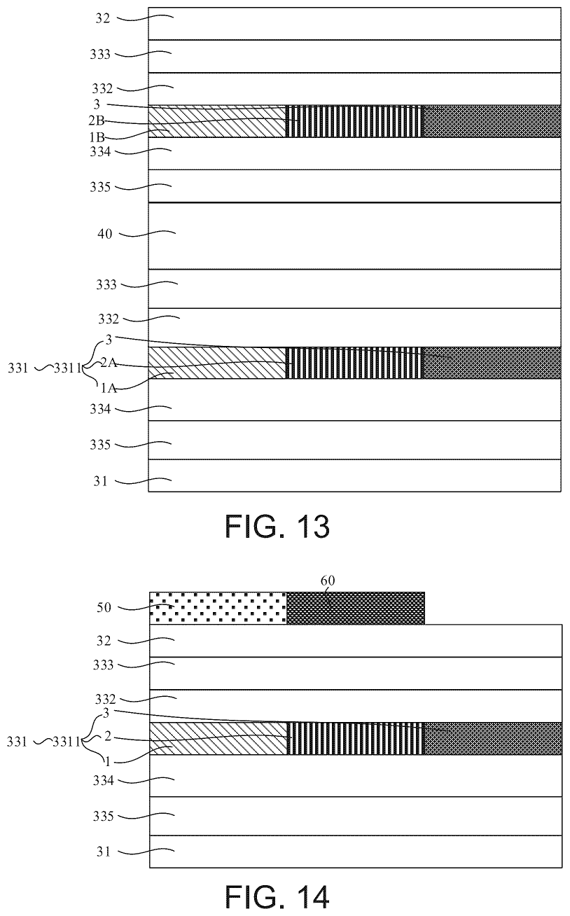

In some embodiments, as shown in FIG. 13, at least two light-emitting portions 3311 are disposed in a first direction between the first electrode layer 31 and the second electrode layer 32 that are arranged opposite to each other. The first direction is perpendicular to a plane where the first electrode layer is located. The display panel 100 further includes a charge generation layer (CGL) 40. The charge generation layer is located between two adjacent light-emitting portions 3311 that are disposed in the first direction. The charge generation layer is used to provide carriers (holes or electrons) to the two adjacent light-emitting portions 3311. Excitons in the light-emitting layer 331 in the embodiment of the present disclosure are dispersed in at least two light-emitting portions 3311.

In some embodiments, the charge generation layer 40 includes a hole charge generation layer and an electron charge generation layer. The hole charge generation layer generates holes under action of the first electrode layer 31 and the second electrode layer 32, and then provides holes to a light-emitting portion proximate to the second electrode layer 32. The electron charge generation layer generates electrons under action of the first electrode layer 31 and the second electrode layer 32, and then provides electrons to a light-emitting portion proximate to the first electrode layer 31.

In some embodiments, as shown in FIG. 13, a first green light-emitting portion 2A and a second green light-emitting portion 2B are provided between the first electrode layer 31 and the second electrode layer 32 that are arranged opposite to each other. The first green light-emitting portion 2A is closer to the first electrode layer 31 than the second green light-emitting portion 2B. The blue thermally-activated delayed fluorescent material can be set according to actual conditions. For example, a material of the first green light-emitting portion 2A includes a main body material, a fluorescent material and a blue thermally-activated delayed fluorescent material, and a material of the second green light-emitting portion 2B includes a main body material and a fluorescent material. Alternatively, for example, the material of the first green light-emitting portion 2A includes a main body material and a fluorescent material, and the material of the second green light-emitting portion 2B includes a main body material, a fluorescent material and a blue thermally-activated delayed fluorescent material. Yet alternatively, for example, the material of the first green light-emitting portion 2A includes a main body material, a fluorescent material and a blue thermally-activated delayed fluorescent material, and the material of the second green light-emitting portion 2B includes a main body material, a fluorescent material and a blue thermally-activated delayed fluorescent material.

In some embodiments, as shown in FIG. 13, a first red light-emitting portion 1A and a second red light-emitting portion 1B are disposed between the first electrode layer 31 and the second electrode layer 32 that are arranged opposite to each other. The first red light-emitting portion 1A is closer to the first electrode layer 31 than the second red light-emitting portion 1B. The green thermally-activated delayed fluorescent material can be set according to actual conditions. For example, a material of the first red light-emitting portion 1A includes a main body material, a fluorescent material and a green thermally-activated delayed fluorescent material, and a material of the second red light-emitting portion 1B includes a main body material and a fluorescent material. Alternatively, for example, the material of the first red light-emitting portion 1A includes a main body material and a fluorescent material, and the material of the second red light-emitting portion 1B includes a main body material, a fluorescent material, and a green thermally-activated delayed fluorescent material. Yet alternatively, for example, the material of the first red light-emitting portion 1A includes a main body material, a fluorescent material and a green thermally-activated delayed fluorescent material, and the material of the second red light-emitting portion 1B includes a main body material, a fluorescent material and a green thermally-activated delayed fluorescent material.

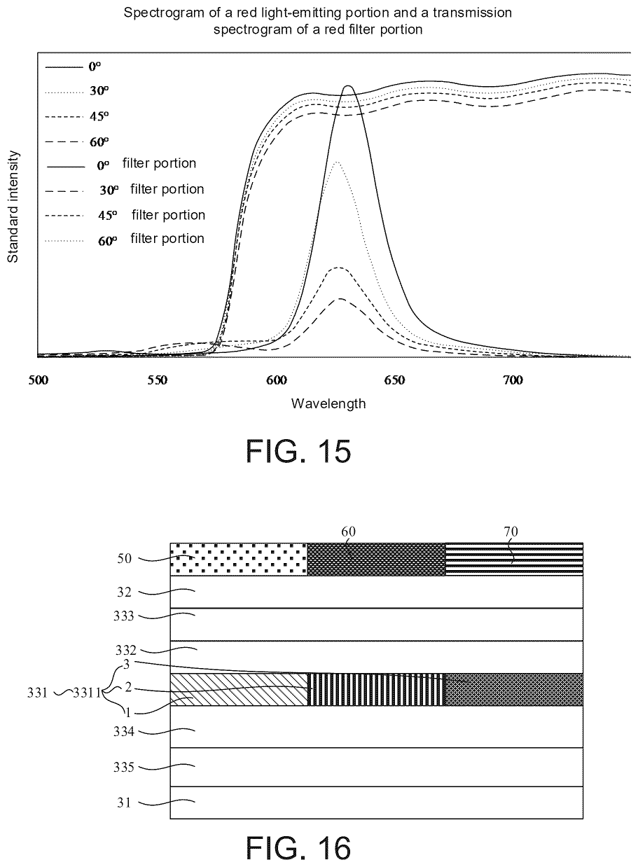

In some embodiments, as shown in FIG. 14, the display panel 100 further includes a red filter portion 50 and a green filter portion 60. The red filter portion 50 is located on a side of the second electrode layer 32 away from the first electrode layer 31. An orthographic projection of the red filter portion 50 on a reference plane covers an orthographic projection of the red light-emitting portion 1 on the reference plane. As shown in FIG. 15, the red filter portion 50 is used to transmit light with a wavelength greater than or equal to 575 nm (for example, transmittance of the light with the wavelength greater than or equal to 575 nm is greater than 95%). In this way, light with a wavelength less than 575 nm in the red light-emitting portion 1 cannot transmit the red filter portion 50, which can reduce the risk that the white screen of the display panel 100 turns yellow. The reference plane is parallel to a surface of the first electrode layer 31 close to the second electrode layer 32. A material of the red filter portion 50 includes an organic material. For example, the material of the red filter portion 50 includes at least one of polymethyl methacrylate, general purpose polymers of polystyrene, polymer derivatives with phenolic groups, acryloyl polymers, imide polymers, aryl ether polymers, amide polymers, fluorine polymers, parylene polymers, or vinyl alcohol polymers.

As shown in FIG. 14, the green filter portion 60 is located on the side of the second electrode layer 32 away from the first electrode layer 31. An orthographic projection of the green filter portion 60 on the reference plane covers an orthographic projection of the green light-emitting portion 2 on the reference plane. The green filter portion 60 is used to transmit light with a wavelength in a range of 500 nm to 580 nm (for example, transmittance of the light with the wavelength in a range of 500 nm to 580 nm is greater than 95%). In this way, blue light with a wavelength less than 500 nm in the green light-emitting portion 2 cannot transmit the green filter portion 60, which can reduce a risk that the white screen of the display panel 100 turns blue. A material of the green filter portion 60 may be the same as the material of the red filter portion 50.

In some embodiments, as shown in FIG. 16, the display panel 100 further includes a blue filter portion 70. The blue filter portion 70 is located on the side of the second electrode layer 32 away from the first electrode layer 31. An orthographic projection of the blue filter portion 70 on the reference plane covers an orthographic projection of the blue light-emitting portion 3 on the reference plane. The blue filter portion 70 is used to transmit light with a wavelength in a range of 380 nm to 530 nm. Transmittance of light with a wavelength in a range of 450 nm to 460 nm is high (for example, the transmittance is greater than 80%).

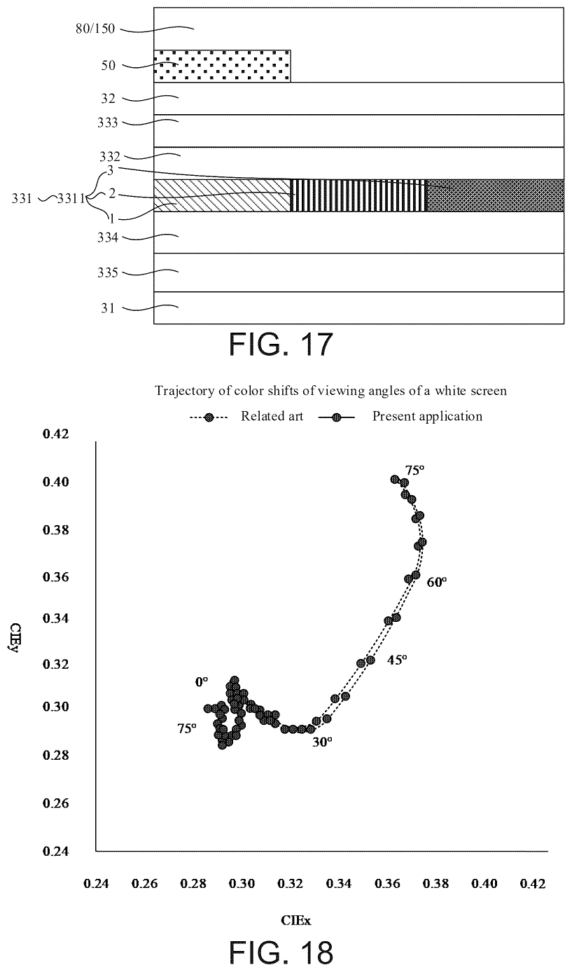

In some other embodiments, as shown in FIG. 17, the display panel 100 includes a red filter portion 50. The red filter portion 50 is located on a side of the second electrode layer 32 away from the first electrode layer 31. An orthographic projection of the red filter portion 50 on the reference plane covers an orthographic projection of the red light-emitting portion 1 on the reference plane. The red filter portion 50 is used to transmit light with a wavelength greater than or equal to 575 nm (for example, transmittance of the light with the wavelength greater than or equal to 575 nm is greater than 95%). In this way, light with a wavelength less than 575 nm in the red filter portion 50 cannot transmit the red filter portion 50, which can reduce the risk that the white screen of the display panel 100 turns yellow.

A material of at least one blue light-emitting portion 3 further includes a red thermally-activated delayed fluorescent material. Similar to the red light-emitting portion 1, there is also incomplete energy transfer among the main body material, the red thermally-activated delayed fluorescent material and the blue fluorescent material in the blue light-emitting portion 3. Red light in the blue light-emitting portion 3 and cyan light in the green light-emitting portion 2 (the cyan light being a mixture of blue light and green light) can be mixed into white light. In this way, a risk of the white screen of the display panel 100 turns cyan may be reduced.

In some embodiments, as shown in FIG. 16, the display panel 100 further includes a green filter portion 60 and a blue filter portion 70. The green filter portion 60 is located on the side of the second electrode layer 32 away from the first electrode layer 31. An orthographic projection of the green filter portion 60 on the reference plane covers an orthographic projection of the green light-emitting portion 2 on the reference plane. The green filter 60 is used to transmit light with a wavelength in a range of 480 nm to 580 nm. Transmittance of light with a wavelength in a range of 420 nm to 430 nm is relatively high (for example, the transmittance is greater than 80%).

The blue filter portion 70 is located on the side of the second electrode layer 32 away from the first electrode layer 31. An orthographic projection of the blue filter portion 70 on the reference plane covers an orthographic projection of the blue light-emitting portion 3 on the reference plane. The blue filter portion 70 is used to transmit light with a wavelength in a range of 380 nm to 530 nm. Transmittance of light with a wavelength in a range of 450 nm to 460 nm is relatively high (for example, the transmittance is greater than 80%).

In some embodiments, as shown in FIG. 3, the display panel further includes a first protective adhesive layer 80. The first protective adhesive layer 80 is located on the side of the second electrode layer 32 away from the first electrode layer 31, so that the first protective adhesive layer 80 can reduce a risk that the second electrode layer 32 is corroded by water and oxygen. A surface of the first protective adhesive layer 80 away from the first electrode layer 31 is substantially parallel to the reference surface.

In a case where the display panel 100 includes a red filter portion 50, as shown in FIG. 17, a portion of the first protective adhesive layer 80 is located on a side of the red filter portion 50 away from the second electrode layer 32. Thus, the first protective adhesive layer 80 can reduce a risk that the red filter portion 50 is corroded by water and oxygen.

In some embodiments, the display panel 100 further includes a capping layer 90 (CPL). The capping layer 90 is located on the side of the second electrode layer 32 away from the first electrode layer 31.

In some embodiments, as shown in FIG. 2, the display panel 100 further includes a pixel defining layer 110. The pixel defining layer 110 is located between the first electrode layer 31 and the second electrode layer 32. The pixel defining layer 110 is provided with a plurality of pixel openings 111, and one pixel opening 111 is provided with one light-emitting portion 3311 therein.

In some embodiments, as shown in FIG. 2, the display panel 100 further includes a black matrix 120. The black matrix 120 is located on the side of the second electrode layer 32 away from the first electrode layer 32. The black matrix 120 is used to separate light emitted from different light-emitting portions 3311, and has a function of reducing reflected light generated after external ambient light enters an interior of the display panel 100. As shown in FIG. 2, a plurality of avoidance openings 121 are provided in the black matrix 120, and an orthographic projection of one avoidance opening 121 on the reference plane covers an orthographic projection of one pixel opening 111 on the reference plane.

In a case where the display panel 100 includes a red filter portion 50, the red filter portion 50 is located on a side of the black matrix 120 away from the substrate 10. An orthographic projection of the red filter portion 50 on the reference plane covers an orthographic projection of an avoidance opening 121 corresponding to the red light-emitting portion 1 on the reference plane.

In a case where the display panel 100 includes a green filter portion 60, the green filter portion 60 is located on the side of the black matrix 120 away from the substrate 10. An orthographic projection of the green filter portion 60 on the reference plane covers an orthographic projection of an avoidance opening 121 corresponding to the green light-emitting portion 2 on the reference plane.

In a case where the display panel 100 includes a blue filter portion 70, the blue filter portion 70 is located on the side of the black matrix 120 away from the substrate 10. An orthographic projection of the blue filter portion 70 on the reference plane covers an orthographic projection of an avoidance opening 121 corresponding to the blue light-emitting portion 3 on the reference plane.

In some embodiments, the display panel further includes an encapsulation layer 140, and the encapsulation layer 140 is located on the side of the second electrode layer 32 away from the first electrode layer 31. The encapsulation layer 140 may be an encapsulation film. In some embodiments, the encapsulation layer 140 may include one layer of encapsulation film, or two or more layers of encapsulation films that are stacked. For example, the encapsulation layer includes three layers of encapsulation films that are stacked in sequence.

In a case where the encapsulation layer 140 includes the three layers of encapsulation films that are stacked in sequence, a material of an encapsulation film located in a middle layer is an organic material, and materials of encapsulation films located on both sides are inorganic materials. The organic material may be, for example, polymethyl methacrylate or PI.

The driving circuit stack 20 is exemplarily described below in combination with a film layer structure of the display panel 100.

For example, as shown in FIG. 2, along a direction perpendicular to the substrate 10 and away from the substrate 10, the display panel 100 sequentially includes a semiconductor layer ACT, a first gate conductive layer GT1, a second gate conductive layer GT2, a first source-drain conductive layer SD1 and a second source-drain conductive layer SD2.

It should be understood that, as shown in FIG. 2, an insulating film layer is provided between each two adjacent layers of the semiconductor layer ACT, the first gate conductive layer GT1, the second gate conductive layer GT2, the first source-drain conductive layer SD1 and the second source-drain conductive layer SD2. For example, the insulating film layer is a first gate insulating layer GI1, an interlayer insulating layer ILD1, a second gate insulating layer GI2, a first flat layer PLN1 and a second flat layer PLN2, which are not specifically limited in embodiments of the present disclosure.

As shown in FIG. 2, the first gate conductive layer GT1 includes a gate electrode 214 of the thin film transistor 21 and a first electrode plate 221 of the storage capacitor 22. The second gate conductive layer GT2 includes a second electrode plate 222 of the storage capacitor 22. The first source-drain conductive layer SD1 includes a source electrode 212 and a drain electrode 213 of the thin film transistor 21.

Embodiments of the present disclosure further provide a display panel 100. As shown in FIG. 17, the display panel 100 includes a red filter portion 50. The red filter portion 50 is located on a side of a second electrode layer 32 away from a first electrode layer 31, and an orthographic projection of the red filter portion 50 on a reference plane covers an orthographic projection of a corresponding red light-emitting portion 1 on the reference plane. As shown in FIG. 15, the red filter portion 50 is used to transmit light with a wavelength greater than or equal to 575 nm (for example, transmittance of the light with the wavelength greater than or equal to 575 nm is greater than 95%). In this way, light with a wavelength less than 575 nm in the red light-emitting portion 1 cannot transmit the red filter portion 50, which can reduce a risk that a white screen of the display panel 100 turns yellow. A material of the red filter portion 50 includes an organic material. For example, the material of the red filter portion 50 includes at least one of polymethyl methacrylate, general purpose polymers of polystyrene, polymer derivatives with phenolic groups, acryloyl polymers, imide polymers, aryl ether polymers, amide polymers, fluorine polymers, paraxylene polymers, or vinyl alcohol polymers. The reference plane is parallel to a surface of the first electrode layer 31 close to the second electrode layer 32.

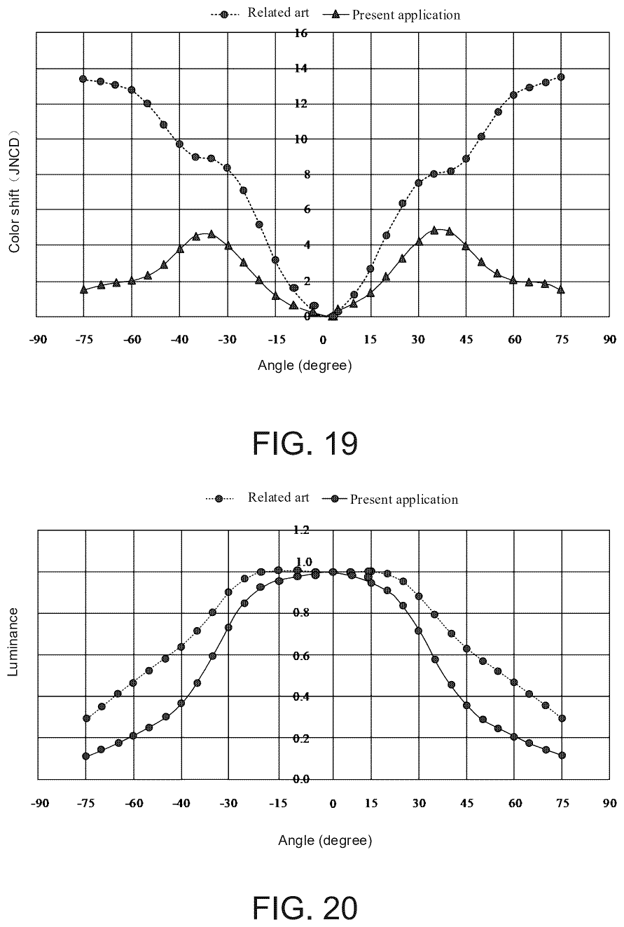

The display panel 100 is tested based on the above structure and the following test results are obtained. As shown in FIG. 18, in a case where the angle is 75°, color coordinates of the display panel 100 in the present application are closer to white color coordinates compared with the related art. As shown in FIG. 19, in a case of the same angle, compared with the related art, a color shift value of the display panel 100 in the present application is reduced, and display effect of the display panel 100 is better. As shown in FIG. 20, in a case of the same angle, compared with the related art, a luminance value of the display panel 100 in the present application is increased, and the display effect of the display panel 100 is better.

In some embodiments, as shown in FIG. 14, the display panel 100 further includes a green filter portion 60. The green filter portion 60 is located on the side of the second electrode layer 32 away from the first electrode layer 31, and an orthographic projection of the green filter portion 60 on the reference plane covers an orthographic projection of the green light-emitting portion 2 on the reference plane. The green filter portion 60 is used to transmit light with a wavelength in a range of 480 nm to 580 nm. Transmittance of light with a wavelength in a range of 420 nm to 430 nm is relatively high (for example, the transmittance is greater than 80%).

In some embodiments, as shown in FIG. 16, the display panel 100 further includes a blue filter portion 70. The blue filter portion 70 is located on the side of the second electrode layer 32 away from the first electrode layer 31, and an orthographic projection of the blue filter portion 70 on the reference plane covers an orthographic projection of the blue light-emitting portion 3 on the reference plane. The blue filter portion 70 is used to transmit light with a wavelength in a range of 380 nm to 530 nm. Transmittance of light with a wavelength in a range of 450 nm to 460 nm is relatively high (for example, the transmittance is greater than 80%).

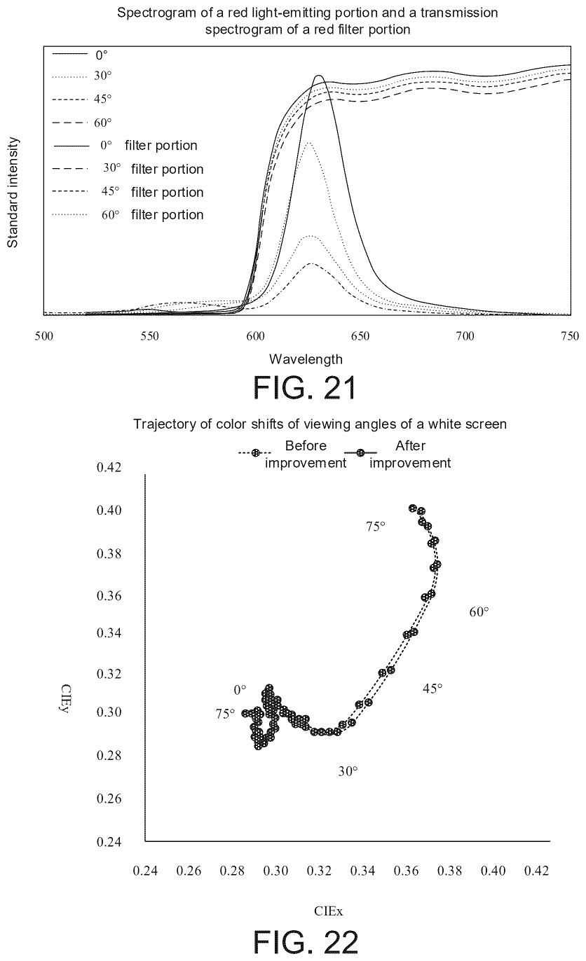

In some embodiments, as shown in FIG. 21, the red filter portion is used to transmit light with a wavelength greater than or equal to 600 nm (for example, transmittance of the light with the wavelength greater than or equal to 600 nm is greater than 95%). In this way, light with a wavelength less than 600 nm in the red filter portion cannot transmit the red filter portion, which can reduce a risk that the white screen of the display panel 100 turns pink.

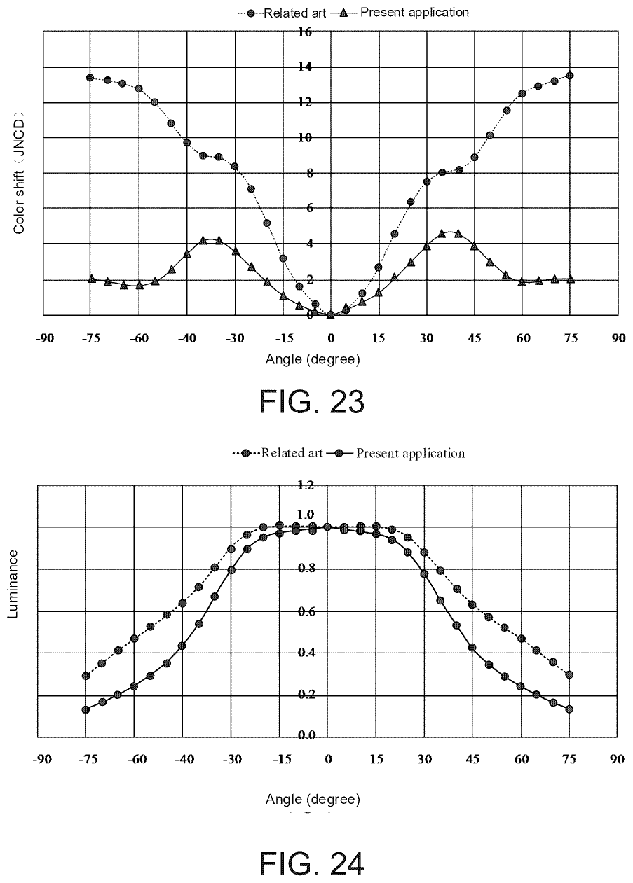

The display panel 100 is tested based on the above structure, and the following test results are obtained. As shown in FIG. 22, in a case where the angle is 75°, color coordinates of the display panel 100 in the present application are closer to white color coordinates compared with the related art. As shown in FIG. 23, in a case of the same angle, compared with the related art, a color shift value of the display panel 100 in the present application is reduced, and the display effect of the display panel 100 is better. As shown in FIG. 24, in a case of the same angle, compared with the related art, a luminance value of the display panel 100 in the present application is increased, and the display effect of the display panel 100 is better.

In some embodiments, as shown in FIG. 17, the display panel 100 further includes a second protective adhesive layer 150. A portion of the second protective adhesive layer 150 is located on a side of the red filter portion 50 away from the second electrode layer 32, and a portion of the second protective adhesive layer 150 is located on the side of the second electrode layer 32 away from the first electrode layer 31. In this way, the second protective adhesive layer 150 can reduce a risk that the red filter portion and the second electrode layer 32 are corroded by water and oxygen. A surface of the second protective adhesive layer 150 away from the first electrode layer 31 is substantially parallel to the reference plane.

In some embodiments, as shown in FIG. 13, at least two light-emitting portions 3311 are disposed in a first direction between the first electrode layer 31 and the second electrode layer 32 that are arranged opposite to each other. The display panel 100 further includes a charge generation layer 40. The charge generation layer 40 is located between two adjacent light-emitting portions 3311 that are disposed in the first direction. The charge generation layer 40 is used to provide carriers (holes or electrons) to the two adjacent light-emitting portions 3311. Excitons in the light-emitting layer 331 in the embodiment of the present disclosure are dispersed in at least two light-emitting portions 3311.

In some embodiments, the charge generation layer 40 includes a hole charge generation layer and an electron charge generation layer. The hole charge generation layer generates holes under action of the first electrode layer 31 and the second electrode layer 32, and then provides holes to a light-emitting portion 3311 proximate to the second electrode layer 32. The electron charge generation layer generates electrons under action of the first electrode layer 31 and the second electrode layer 32, and then provides electrons to a light-emitting portion 3311 proximate to the first electrode layer 31.

In some embodiments, as shown in FIG. 13, a first red light-emitting portion 1A and a second red light-emitting portion 1B are disposed in the first direction between the first electrode layer 31 and the second electrode layer 32 that are arranged opposite to each other. The first red light-emitting portion 1A is closer to the first electrode layer 31 than the second red light-emitting portion 1B. The green thermally-activated delayed fluorescent material can be set according to actual conditions. For example, a material of the first red light-emitting portion 1A includes a main body material, a fluorescent material and a green thermally-activated delayed fluorescent material, and a material of the second red light-emitting portion 1B includes a main body material and a fluorescent material. Alternatively, for example, the material of the first red light-emitting portion 1A includes a main body material and a fluorescent material, and the material of the second red light-emitting portion 1B includes a main body material, a fluorescent material, and a green thermally-activated delayed fluorescent material. Yet alternatively, for example, the material of the first red light-emitting portion 1A includes a main body material, a fluorescent material and a green thermally-activated delayed fluorescent material, and the material of the second red light-emitting portion 1B includes a main body material, a fluorescent material and a green thermally-activated delayed fluorescent material.

The foregoing descriptions are merely specific implementations of the present disclosure, but the protection scope of the present disclosure is not limited thereto. Any changes or replacements that a person skilled in the art could conceive of within the technical scope of the present disclosure shall be included in the protection scope of the present disclosure. Therefore, the protection scope of the present disclosure should be determined by the protection scope of the claims.

1. A display panel, comprising:
a first electrode layer including a reflective electrode layer;
a second electrode layer arranged opposite to the first electrode layer, the second electrode layer including a transflective electrode layer;
a light-emitting layer located between the first electrode layer and the second electrode layer, the light-emitting layer including a plurality of light-emitting portions, and a material of each of the plurality of light-emitting portions including a main body material and a fluorescent material, wherein the plurality of light-emitting portions include a plurality of red light-emitting portions, a plurality of blue light-emitting portions and a plurality of green light-emitting portions, a material of at least one red light-emitting portion of the plurality of red light-emitting portions further includes a green thermally-activated delayed fluorescent material, and a material of at least one green light-emitting portion of the plurality of green light-emitting portions further includes a blue thermally-activated delayed fluorescent material.

2. The display panel according to claim 1, wherein a concentration of the blue thermally-activated delayed fluorescent material of the at least one green light-emitting portion is greater than a concentration of the fluorescent material of the at least one green light-emitting portion.

3. The display panel according to claim 1, wherein a concentration of the blue thermally-activated delayed fluorescent material of the at least one green light-emitting portion is in a range of 35% to 45%, and a concentration of the fluorescent material of the at least one green light-emitting portion is less than 1%.

4. The display panel according to claim 1, wherein a highest occupied molecular orbital energy level of the green thermally-activated delayed fluorescent material is −5.2 eV, and a lowest unoccupied molecular orbital energy level of the green thermally-activated delayed fluorescent material is −3.1 eV; and/or, a highest occupied molecular orbital energy level of the blue thermally-activated delayed fluorescent material is −5.8 eV, and a lowest unoccupied molecular orbital energy level of the blue thermally-activated delayed fluorescent material is −3.0 eV.

5. The display panel according to claim 1, wherein a peak of a photoluminescence spectrum of the green thermally-activated delayed fluorescent material is in a range of 500 nm to 550 nm; and/or a peak of a photoluminescence spectrum of the blue thermally-activated delayed fluorescent material is in a range of 450 nm to 500 nm.

6. The display panel according to claim 1, wherein the green thermally-activated delayed fluorescent material and the blue thermally-activated delayed fluorescent material each include an electron donor functional group and an electron acceptor functional group; and an electron donating ability of the electron donor functional group of the green thermally-activated delayed fluorescent material is greater than an electron donating ability of the electron donor functional group of the blue thermally-activated delayed fluorescent material.

7. The display panel according to claim 6, wherein the electron donor functional group of the green thermally-activated delayed fluorescent material and/or the electron donor functional group of the blue thermally-activated delayed fluorescent material include a carbazole structure, a thiophene structure or a triphenylamine structure; and
the electron acceptor functional group of the green thermally-activated delayed fluorescent material and/or the electron acceptor functional group of the blue thermally-activated delayed fluorescent material include a cyano structure, an anthraquinone structure or a diphenyl sulfone structure.

8. The display panel according to claim 1, wherein
in a case where a first direction is parallel to a line of sight, a peak of aphotoluminescence spectrum of the at least one red light-emitting portion is in a range of 621 nm to 631 nm, a peak of a photoluminescence spectrum of the at least one green light-emitting portion is in a range of 525 nm to 535 nm, and a peak of a photoluminescence spectrum of a blue light-emitting portion is in a range of 455 nm to 465 nm, wherein the first direction is perpendicular to a plane where the first electrode layer of the display panel is located;
in a case where an angle between the first direction and the line of sight is 30°, the peak of the photoluminescence spectrum of the at least one red light-emitting portion is in a range of 618 nm to 628 nm, the peak of the photoluminescence spectrum of the at least one green light-emitting portion is in a range of 520 nm to 530 nm, and the peak of the photoluminescence spectrum of the blue light-emitting portion is in a range of 453 nm to 463 nm;
in a case where the angle between the first direction and the line of sight is 45°, the peak of the photoluminescence spectrum of the at least one red light-emitting portion is in a range of 619 nm to 629 nm, the peak of the photoluminescence spectrum of the at least one green light-emitting portion is in a range of 523 nm to 533 nm, and the peak of the photoluminescence spectrum of the blue light-emitting portion is in a range of 451 nm to 461 nm;
in a case where the angle between the first direction and the line of sight is 60°, the peak of the photoluminescence spectrum of the at least one red light-emitting portion is in a range of 619 nm to 629 nm, the peak of the photoluminescence spectrum of the at least one green light-emitting portion is in a range of 523 nm to 533 nm, and the peak of the photoluminescence spectrum of the blue light-emitting portion is in a range of 452 nm to 462 nm.

9. The display panel according to claim 1, wherein at least two light-emitting portions are disposed in a first direction between the first electrode layer and the second electrode layer that are arranged opposite to each other, and the first direction is perpendicular to a plane where the first electrode layer is located; and
the display panel further comprises:
a charge generation layer located between two adjacent light-emitting portions that are disposed in the first direction, the charge generation layer being configured to provide carriers to the two adjacent light-emitting portions.

10. The display panel according to claim 9, wherein the at least two light-emitting portions include a first green light-emitting portion and a second green light-emitting portion and a material of the first green light-emitting portion and/or a material of the second green light-emitting portion include the blue thermally-activated delayed fluorescent material; and/or
the at least two light-emitting portions include a first red light-emitting portion and a second red light-emitting portion, and a material of the first red light-emitting portion and/or a material of the second red light-emitting portion include the green thermally-activated delayed fluorescent material.

11. (canceled)

12. The display panel according to claim 1, further comprising:
a red filter portion located on a side of the second electrode layer away from the first electrode layer, an orthographic projection of the red filter portion on a reference plane covering an orthographic projection of a corresponding red light-emitting portion on the reference plane; and
a green filter portion located on the side of the second electrode layer away from the first electrode layer, an orthographic projection of the green filter portion on the reference plane covering an orthographic projection of a corresponding green light-emitting portion on the reference plane; or
a red filter portion located on a side of the second electrode layer away from the first electrode layer, an orthographic projection of the red filter portion on a reference plane covering an orthographic projection of a corresponding red light-emitting portion on the reference plane; a green filter portion located on the side of the second electrode layer away from the first electrode layer, an orthographic projection of the green filter portion on the reference plane covering an orthographic projection of a corresponding green light-emitting portion on the reference plane; and a blue filter portion located on the side of the second electrode layer away from the first electrode layer, an orthographic projection of the blue filter portion on the reference plane covering an orthographic projection of a corresponding blue light-emitting portion on the reference plane, wherein
the reference plane is parallel to a surface of the first electrode layer close to the second electrode layer.

13. (canceled)

14. The display panel according to claim 1, further comprising:
a red filter portion located on a side of the second electrode layer away from the first electrode layer, an orthographic projection of the red filter portion on a reference plane covering an orthographic projection of a corresponding red light-emitting portion on the reference plane, and a material of at least one blue light-emitting portion of the plurality of blue light-emitting portions further including a red thermally-activated delayed fluorescent material, wherein the reference plane is parallel to a surface of the first electrode layer close to the second electrode layer.

15. The display panel according to claim 1, further comprising:
a first protective adhesive layer located on a side of the second electrode layer away from the first electrode layer, a surface of the first protective adhesive layer away from the first electrode layer being substantially parallel to a reference surface, wherein the reference surface is parallel to a surface of the first electrode layer close to the second electrode layer.

16. A display panel, comprising:
a first electrode layer including a reflective electrode layer;
a second electrode layer arranged opposite to the first electrode layer, the second electrode layer including a transflective electrode layer;
a light-emitting layer located between the first electrode layer and the second electrode layer, the light-emitting layer including a plurality of light-emitting portions, and a material of each of the plurality of light-emitting portions including a main body material and a fluorescent material, wherein the plurality of light-emitting portions include a plurality of red light-emitting portions, a plurality of blue light-emitting portions and a plurality of green light-emitting portions, and a material of at least one red light-emitting portion of the plurality of red light-emitting portions further includes a green thermally-activated delayed fluorescent material;
a red filter portion located on a side of the second electrode layer away from the first electrode layer, an orthographic projection of the red filter portion on a reference plane covering an orthographic projection of a corresponding red light-emitting portion on the reference plane, wherein the reference plane is parallel to a surface of the first electrode layer close to the second electrode layer.

17. The display panel according to claim 16, wherein the red filter portion is configured to transmit red light with a wavelength greater than or equal to 600 nm.

18. The display panel according to claim 16, further comprising:
a second protective adhesive layer partially located on a side of the red filter portion away from the second electrode layer, and partially located on the side of the second electrode layer away from the first electrode layer, a surface of the second protective adhesive layer away from the first electrode layer being substantially parallel to the reference plane.

19. The display panel according to claim 16, wherein at least two light-emitting portions are disposed in a first direction between the first electrode layer and the second electrode layer that are arranged opposite to each other, wherein the first direction is perpendicular to a plane where the first electrode layer is located, wherein the first direction is perpendicular to a plane where the first electrode layer is located; and
the display panel further comprises:
a charge generation layer located between two adjacent light-emitting portions that are disposed in the first direction, the charge generation layer being configured to provide carriers to the two adjacent light-emitting portions.

20. The display panel according to claim 19, wherein the at least two light-emitting portions include a first red light-emitting portion and a second red light-emitting portion and a material of the first red light-emitting portion and/or a material of the second red light-emitting portion include the green thermally-activated delayed fluorescent material.

21. A display apparatus, comprising the display panel according to claim 1.

22. A display apparatus, comprising the display panel according to claim 16.
